(19) United States
(12) Patent Application Publication
(10) Pub. No.: US 2023/0266582 A1
(43) Pub. Date: Aug. 24, 2023

(54) DRIVING ELEMENT AND DRIVING DEVICE

(71) Applicant: Panasonic Intellectual Property Management Co., Ltd., Osaka (JP)

(72) Inventors: Takami ISHIDA, Osaka (JP); Ryouichi Takayama, Osaka (JP)

(21) Appl. No.: 18/141,252

(22) Filed: Apr. 28, 2023

Related U.S. Application Data
(63) Continuation of application No. PCT/JP21/31903, filed on Aug. 31, 2021.

(30) Foreign Application Priority Data
Nov. 11, 2020 (JP) 2020-188297

(51) Int. Cl. G02B 26/10; H02N 2/02; H02N 2/06

(52) U.S. Cl. CPC G02B 26/105; H02N 2/028; H02N 2/065

(57) ABSTRACT

A driving element includes: a base; a movable part spaced apart from the base in a direction parallel to a rotation axis; a connection part connecting the base and the movable part; a pair of first arm parts extending in a first direction parallel to the rotation axis with the rotation axis located therebetween; a pair of second arm parts extending in a second direction opposite to the first direction, with the rotation axis located therebetween; a coupling part coupling the pair of first arm parts and the pair of second arm parts to the connection part; and a piezoelectric driver disposed on at least either the pair of first arm parts or the pair of second arm parts.

### CROSS REFERENCE TO RELATED APPLICATION

This application is a continuation of International Application No. PCT/JP2021/031903 filed on Aug. 31, 2021, entitled “DRIVING ELEMENT AND DRIVING DEVICE”, which claims priority under 35 U.S.C. Section 119 of Japanese Patent Application No. 2020-188297 filed on Nov. 11, 2020, entitled “DRIVING ELEMENT AND DRIVING DEVICE”. The disclosures of the above applications are incorporated herein by reference.

### BACKGROUND OF THE INVENTION

### Field of the Invention

The present invention relates to a driving element that rotates a movable part by a piezoelectric driver, and a driving device including the driving element, and the driving element and the driving device are suitable for, for example, use for the case of performing scanning with light using a reflection surface located on the movable part.

### Description of Related Art

In recent years, by using micro electro mechanical system (MEMS) technology, driving elements that rotate a movable part have been developed. In this type of driving element, a reflection surface is located on the movable part, thereby allowing scanning to be performed at a predetermined deflection angle with light incident on the reflection surface. This type of driving element is installed in image projection devices such as head-up displays and head-mounted displays. In addition, this type of driving element can also be used in laser radars that use laser beams to detect objects, etc.

For example, International Publication No. 2019/087919 describes a driving element of a type that rotates a movable part by a so-called tuning fork vibrator. Here, piezoelectric drivers are respectively disposed on a pair of arm parts extending along a rotation axis. When AC voltages having phases different from each other by 180° (opposite phases) are applied to these piezoelectric drivers, respectively, the pair of arm parts expand and contract in directions opposite to each other. As a result, the movable part rotates about the rotation axis, and the reflection surface located on the movable part rotates accordingly.

In the driving element configured as described above, it is preferable that the deflection angle of the movable part per unit voltage is larger. In addition, in this configuration, when driving the driving element, the piezoelectric drivers may be damaged by stress generated due to bending of the arm parts. This problem becomes more apparent when the pair of arm parts are bent to a greater extent in order to increase the deflection angle.

### SUMMARY OF THE INVENTION

A driving element according to a first aspect of the present invention includes: a base; a movable part spaced apart from the base in a direction parallel to a rotation axis; a connection part connecting the base and the movable part; a pair of first arm parts extending in a first direction parallel to the rotation axis with the rotation axis located therebetween; a pair of second arm parts extending in a second direction opposite to the first direction, with the rotation axis located therebetween; a coupling part coupling the pair of first arm parts and the pair of second arm parts to the connection part; and a piezoelectric driver disposed on at least either the pair of first arm parts or the pair of second arm parts.

In the driving element according to this aspect, by providing the pair of second arm parts, torsion and stress generated in the first arm parts and the second arm parts when the piezoelectric driver is driven can be reduced, and further, a deflection angle of the movable part when the piezoelectric driver is driven can be increased. Therefore, damaging the piezoelectric driver by stress generated during driving can be suppressed while the deflection angle of the movable part is increased.

A driving element according to a second aspect of the present invention includes: a base; a movable part spaced apart from the base in a direction parallel to a rotation axis; a connection part connecting the base and the movable part; a pair of arm parts extending in a first direction parallel to the rotation axis with the rotation axis located therebetween; a pair of balance adjustment parts extending in a second direction opposite to the first direction, with the rotation axis located therebetween; a coupling part coupling the pair of arm parts and the pair of balance adjustment parts to the connection part; and a piezoelectric driver disposed on at least either the pair of arm parts or the pair of balance adjustment parts.

In the driving element according to this aspect, the same effects as those of the above first aspect can be achieved.

A driving device according to a third aspect of the present invention includes the driving element according to the second aspect and a driving circuit configured to supply a driving voltage to the piezoelectric driver.

In the driving device according to this aspect, the same effects as those of the above first aspect can be achieved.

In the above aspects, the term “extending in a first direction” broadly includes a state where the first arm parts are parallel to the first direction, as well as a state where the direction in which the first arm parts extend includes a component in the first direction, such as a state where the first arm parts are tilted at a predetermined angle from the first direction. Similarly, the term “extending in a second direction” broadly includes a state where the second arm parts are parallel to the second direction, as well as a state where the direction in which the second arm parts extend includes a component in the second direction, such as a state where the second arm parts are tilted at a predetermined angle from the second direction.

The effects and the significance of the present invention will be further clarified by the description of the embodiment below. However, the embodiment below is merely an example for implementing the present invention. The present invention is not limited by the description of the embodiment below in any way.

### BRIEF DESCRIPTION OF THE DRAWINGS

FIG. 1 is a perspective view showing a configuration of a driving element according to an embodiment;

FIG. 2 is a plan view showing the configuration of the driving element according to the embodiment;

FIG. 3 is a diagram showing the waveforms of driving voltages applied to piezoelectric drivers according to the embodiment;

FIG. 4A and FIG. 4B are each a diagram showing a driving state of a movable part when driving signals are supplied to the piezoelectric drivers according to the embodiment;

FIG. 5 is a diagram showing the dimensions of each part used in simulation of stress generated during driving according to the embodiment;

FIG. 6A is a diagram showing a stress distribution simulation result for the embodiment;

FIG. 6B is a diagram showing a stress distribution simulation result for a comparative example.

FIG. 7A is a diagram illustrating a method for setting conditions for Examination 2 for the embodiment;

FIG. 7B is a graph showing the examination results of deflection angle characteristics in Examination 2 for the embodiment;

FIG. 8A and FIG. 8B are each a plan view illustrating another method for disposing the piezoelectric drivers according to Modification 1;

FIG. 9A to FIG. 9C are each a plan view showing a configuration of a driving element according to Modification 2 in which only a first driving unit is disposed;

FIG. 10A and FIG. 10B are each a plan view showing a configuration of a driving element according to another modification; and

FIG. 11 is a diagram showing a configuration of a driving device including the driving element in FIG. 10B.

It should be noted that the drawings are solely for description and do not limit the scope of the present invention by any degree.

### DETAILED DESCRIPTION

Hereinafter, an embodiment of the present invention will be described with reference to the drawings. For convenience, in each drawing, X, Y, and Z axes that are orthogonal to each other are additionally shown. The Y-axis direction is a direction parallel to a rotation axis of a driving element, and the Z-axis direction is a direction perpendicular to a reflection surface located on a movable part.

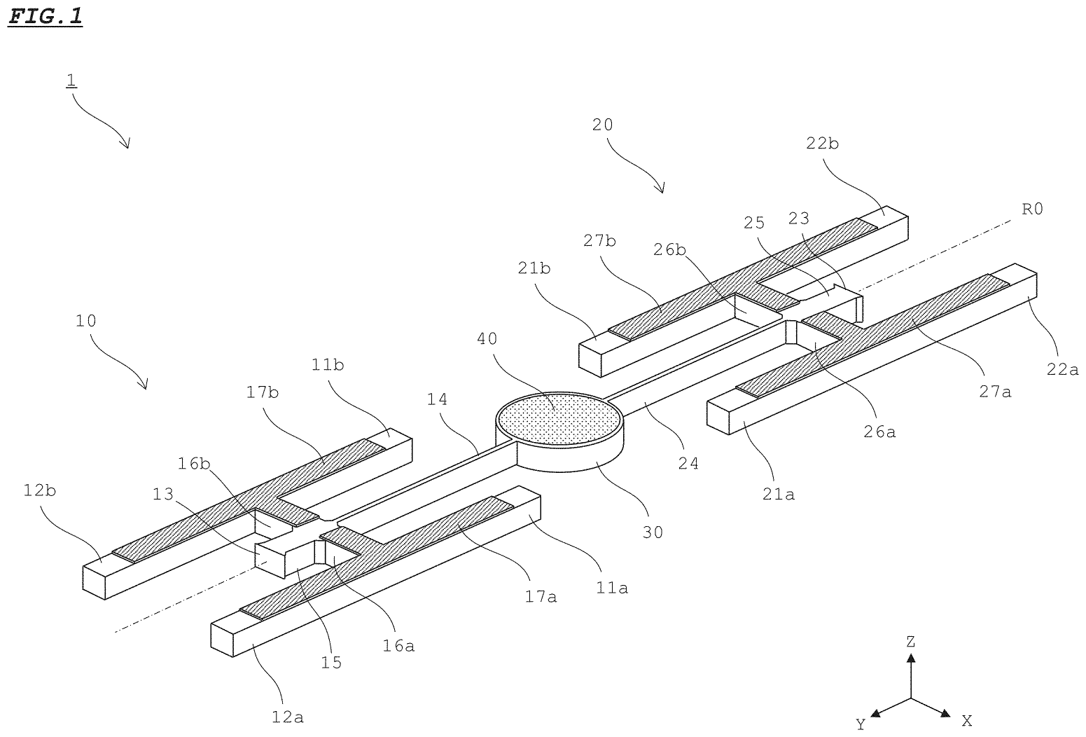

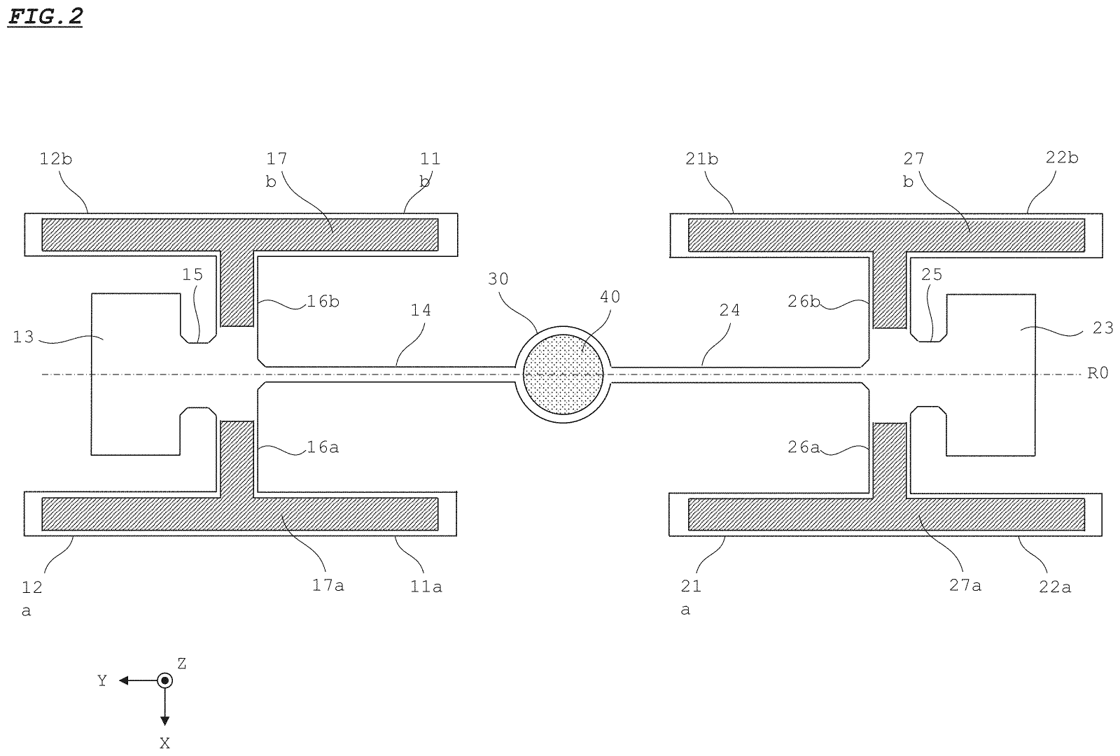

FIG. 1 is a perspective view showing a configuration of a driving element 1, and FIG. 2 is a plan view showing the configuration of the driving element 1. For convenience, parts 13 and 23 of a base (hereinafter, referred to as “bases 13 and 23”) are shown in FIG. 1.

As shown in FIG. 1 and FIG. 2, the driving element 1 includes a first driving unit 10, a second driving unit 20, a movable part 30, and a reflection surface 40. The first driving unit 10 and the second driving unit 20 rotate the movable part 30 about a rotation axis R0 in response to driving signals supplied thereto from driving circuits which are not shown. The reflection surface 40 is located on the upper surface of the movable part 30, and reflects incident light in a direction corresponding to a deflection angle of the movable part 30. Accordingly, scanning is performed with the light (e.g., laser beam) incident on the reflection surface 40 as the movable part 30 rotates. Here, the movable part 30 and the reflection surface 40 may be formed of the same member.

The first driving unit 10 includes a pair of first arm parts 11a and 11b, a pair of second arm parts 12a and 12b, the base 13, a first connection part 14, a second connection part 15, coupling parts 16a and 16b, and piezoelectric drivers 17a and 17b. In a plan view, the first driving unit 10 has a shape symmetrical in the X-axis direction. The piezoelectric driver 17a extends along each of the upper surfaces of the first arm part 11a, the second arm part 12a, and the coupling part 16a. In addition, the piezoelectric driver 17b extends along each of the upper surfaces of the first arm part 11b, the second arm part 12b, and the coupling part 16b.

The thicknesses of the parts of the first driving unit 10 other than the piezoelectric drivers 17a and 17b are uniform. However, the thicknesses of these parts do not necessarily have to be uniform, and, for example, the thickness of the base 13 may be larger than the thicknesses of the other parts. The parts of the first driving unit 10 other than the piezoelectric drivers 17a and 17b are, for example, integrally formed from silicon or the like. However, the material forming these parts is not limited to silicon, and may be another material. The material forming these parts is preferably a material having high mechanical strength and Young's modulus, such as metal, crystal, glass, and resin. As such a material, in addition to silicon, titanium, stainless steel, Elinvar, a brass alloy, etc., can be used.

The pair of first arm parts 11a and 11b are disposed symmetrically with the rotation axis R0 located therebetween, and extend in a first direction (Y-axis negative direction) parallel to the rotation axis R0. The lengths and the cross-sectional areas of the first arm parts 11a and 11b are equal to each other. The widths and the thicknesses of the first arm parts 11a and 11b are uniform over the overall lengths thereof. The cross-sectional shapes of the first arm parts 11a and 11b when the first arm parts 11a and 11b are cut along a plane parallel to the X-Z plane are rectangular. The first arm parts 11a and 11b are spaced apart from the rotation axis R0 by the same distance in directions opposite to each other.

The pair of second arm parts 12a and 12b are disposed symmetrically with the rotation axis R0 located therebetween, and extend in a second direction (Y-axis positive direction) opposite to the first direction (Y-axis negative direction). The lengths and the cross-sectional areas of the second arm parts 12a and 12b are equal to each other. The widths and the thicknesses of the second arm parts 12a and 12b are uniform over the overall lengths thereof. The cross-sectional shapes of the second arm parts 12a and 12b when the second arm parts 12a and 12b are cut along a plane parallel to the X-Z plane are rectangular. The second arm parts 12a and 12b are spaced apart from the rotation axis R0 by the same distance in directions opposite to each other.

The first arm part 11a and the second arm part 12a on the X-axis positive side are aligned on the same straight line, and have the same cross-sectional shape and cross-sectional area as each other. The first arm part 11b and the second arm part 12b on the X-axis negative side are aligned on the same straight line, and have the same cross-sectional shape and cross-sectional area as each other. As described later, the lengths of the second arm parts 12a and 12b are adjusted to lengths that can relieve the stress and torsion generated in the first arm parts 11a and 11b when the movable part 30 is driven and that can increase the deflection angle of the movable part 30.

The base 13 is for connecting the first driving unit 10 to an external structural member. That is, the first driving unit 10 is supported by an external structural member via the base 13. The base 13 and the movable part 30 are linearly aligned in the Y-axis direction so as to be spaced apart from each other by a predetermined distance. The base 13 and the movable part 30 are connected to each other by the first connection part 14 and the second connection part 15.

The second connection part 15 extends parallel to the Y-axis direction along the rotation axis R0. The cross-sectional shape of the second connection part 15 when the second connection part 15 is cut along a plane parallel to the X-Z plane is rectangular. The first connection part 14 extends in the Y-axis negative direction from an end portion on the Y-axis negative side of the second connection part 15. An end portion on the Y-axis negative side of the first connection part 14 is connected to the side surface of the movable part 30. The cross-sectional shape of the first connection part 14 when the first connection part 14 is cut along a plane parallel to the X-Z plane is rectangular. The width in the X-axis direction of the first connection part 14 is much smaller than the width in the X-axis direction of the second connection part 15. The first connection part 14 has a plate-like shape that is long in the Y-axis direction.

The second connection part 15 does not necessarily have to extend in a straight manner along the rotation axis R0, and may extend, for example, in the Y-axis direction while meandering in the X-axis direction. Similarly, the first connection part 14 does not necessarily have to extend in a straight manner along the rotation axis R0, and may extend, for example, in the Y-axis direction while meandering in the X-axis direction.

The piezoelectric drivers 17a and 17b each have a lamination structure in which electrodes are disposed above and below a piezoelectric body having a predetermined thickness, respectively. The piezoelectric body is made of, for example, a piezoelectric material having a high piezoelectric constant, such as lead zirconate titanate (PZT). The electrodes are made of a material having low electrical resistance and high heat resistance, such as platinum (Pt). The piezoelectric drivers 17a and 17b are disposed on the upper surfaces of the first arm parts 11a and 11b, the second arm parts 12a and 12b, and the coupling parts 16a and 16b by forming layer structures each including a piezoelectric body and upper and lower electrodes, on the upper surfaces of these parts by a sputtering method or the like.

The second driving unit 20 includes a pair of first arm parts 21a and 21b, a pair of second arm parts 22a and 22b, the base 23, a first connection part 24, a second connection part 25, coupling parts 26a and 26b, and piezoelectric drivers 27a and 27b. In a plan view, the second driving unit 20 has a shape symmetrical in the X-axis direction. The piezoelectric driver 27a extends along each of the upper surfaces of the first arm part 21a, the second arm part 22a, and the coupling part 26a. In addition, the piezoelectric driver 27b extends along each of the upper surfaces of the first arm part 21b, the second arm part 22b, and the coupling part 26b.

The configuration of each part of the second driving unit 20 is the same as the configuration of the corresponding part of the first driving unit 10. The second driving unit 20 is disposed in an orientation opposite to that of the first driving unit 10 such that the first connection part 24 extends in the Y-axis positive direction from the second connection part 25. The first connection part 24 extends along the rotation axis R0. That is, the first connection parts 14 and 24 are aligned on the same straight line. An end portion on the Y-axis positive side of the first connection part 24 is connected to the side surface of the movable part 30.

The movable part 30 has a circular shape in a plan view. Side surface positions of the movable part 30 that are symmetrical with respect to the central axis of the movable part 30 are connected to the first connection part 14 of the first driving unit 10 and the first connection part 24 of the second driving unit 20, respectively. The thickness of the movable part 30 is equal to those of the first connection parts 14 and 24. However, the thickness of the movable part 30 does not necessarily have to be equal to those of the first connection parts 14 and 24. For example, the thickness of the movable part 30 may be larger than those of the first connection parts 14 and 24. The movable part 30 is integrally formed with the first connection parts 14 and 24.

The reflection surface 40 is formed by forming a reflection film made of a material having a high reflectance, on the upper surface of the movable part 30. The material forming the reflection film can be selected from among, for example, metals such as gold, silver, copper, and aluminum, metal compounds thereof, silicon dioxide, titanium dioxide, etc. The reflection film may be a dielectric multilayer film. In addition, the reflection surface 40 may be formed by polishing the upper surface of the movable part 30. The reflection surface 40 does not necessarily have to be flat, and may be a concave or convex curved surface.

In a plan view, the driving element 1 is symmetrical in the X-axis direction and symmetrical in the Y-axis direction. The parts of the driving element 1 other than the piezoelectric drivers 17a, 17b, 27a, and 27b and the reflection surface 40 are configured, for example, by cutting a silicon substrate having a predetermined thickness into the shape shown in FIG. 2 by etching treatment. The piezoelectric drivers 17a, 17b, 27a, and 27b and the reflection surface 40 are formed in the corresponding regions by a film formation technique such as a sputtering method. Thus, the driving element 1 shown in FIG. 1 and FIG. 2 is configured.

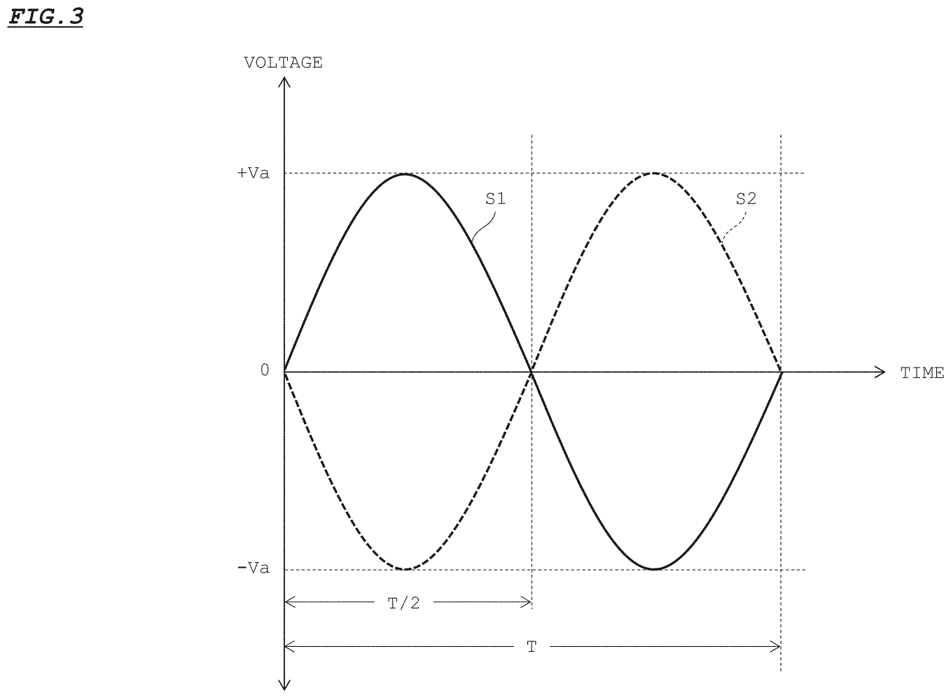

FIG. 3 is a diagram showing the waveforms of driving voltages applied to the piezoelectric drivers 17a, 17b, 27a, and 27b.

Driving signals S1 and S2 are AC signals each of which has a predetermined frequency and swings in the range between +Va and −Va. Periods T of the driving signals S1 and S2 are equal to each other. The phases of the driving signals S1 and S2 are shifted from each other by T/2. That is, the driving signals S1 and S2 are AC voltages having phases opposite to each other.

In the configuration in FIG. 1 and FIG. 2, the driving signal S1 is supplied to the piezoelectric drivers 17a and 27a on the X-axis positive side, and the driving signal S2 is supplied to the piezoelectric drivers 17b and 27b on the X-axis negative side. Accordingly, the movable part 30 and the reflection surface 40 rotate at a predetermined deflection angle around the rotation axis R0.

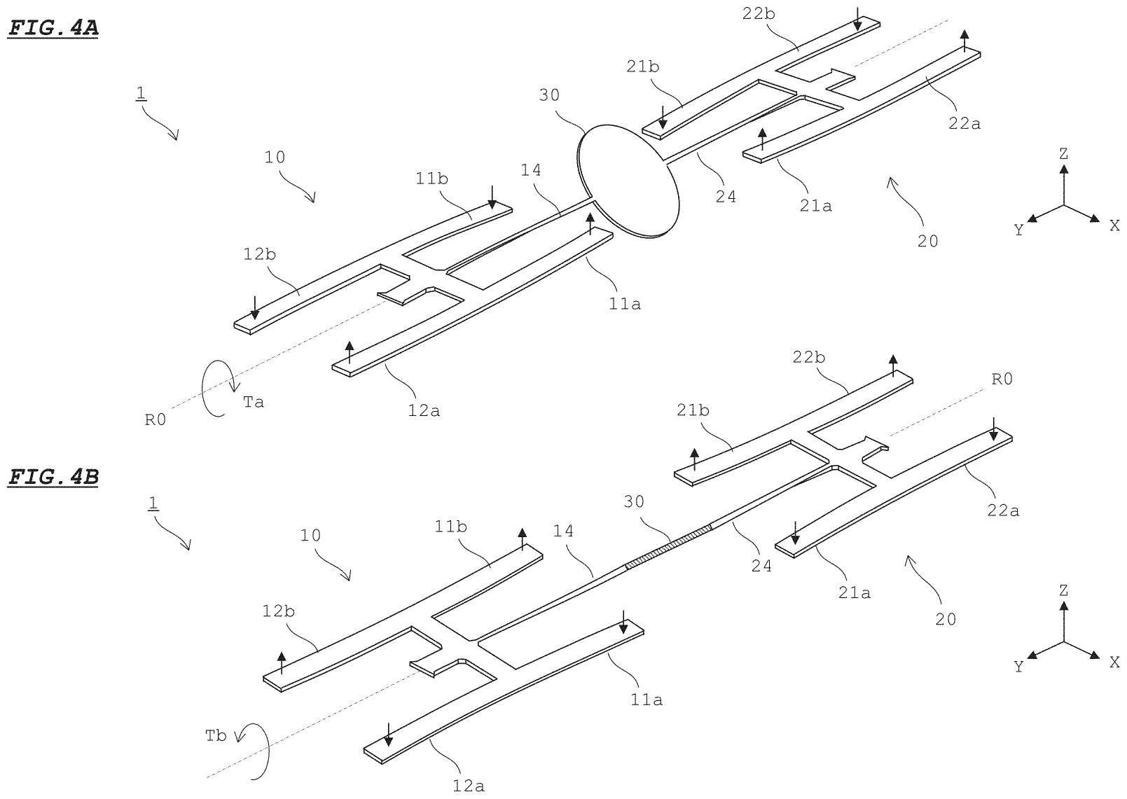

FIGS. 4A and 4B are each a diagram showing a driving state of the movable part 30 when the driving signals S1 and S2 shown in FIG. 3 are supplied to the corresponding piezoelectric drivers, respectively.

When the driving signals S1 and S2 shown in FIG. 3 are supplied to the corresponding piezoelectric drivers, respectively, the first arm parts 11a and 21a and the second arm parts 12a and 22a on the X-axis positive side, and the first arm parts 11b and 21b and the second arm parts 12b and 22b on the X-axis negative side are repeatedly deformed in directions opposite to each other in the Z-axis direction. Accordingly, the coupling parts 16a and 26a on the X-axis positive side and the coupling parts 16b and 26b on the X-axis negative side vibrate in phases opposite to each other, generating torques in the same rotation direction around the rotation axis R0. These torques are transmitted to the first connection parts 14 and 24, whereby the movable part 30 vibrates around the rotation axis R0. Thus, the reflection surface 40 rotates at a predetermined deflection angle.

For example, at the timing in FIG. 4A, the first arm parts 11a and 21a and the second arm parts 12a and 22a on the X-axis positive side are deformed upward, and the first arm parts 11b and 21b and the second arm parts 12b and 22b on the X-axis negative side are deformed downward. Accordingly, torque Ta is generated around the rotation axis R0, so that the movable part 30 rotates clockwise when viewed in the Y-axis negative direction.

Also, at the timing in FIG. 4B, the first arm parts 11a and 21a and the second arm parts 12a and 22a on the X-axis positive side are deformed downward, and the first arm parts 11b and 21b and the second arm parts 12b and 22b on the X-axis negative side are deformed upward. Accordingly, torque Tb is generated around the rotation axis R0, so that the movable part 30 rotates counterclockwise when viewed in the Y-axis negative direction.

Thus, the driving element 1 resonates at a predetermined resonance frequency, and the movable part 30 repeatedly rotates clockwise and counterclockwise at a predetermined deflection angle. Accordingly, the reflection surface 40 which is located on the movable part 30 repeatedly rotates clockwise and counterclockwise at the predetermined deflection angle. As a result, scanning is performed at the predetermined deflection angle with light (e.g., laser beam) incident on the reflection surface 40.

Although FIGS. 4A and 4B show a state where the first driving unit 10 and the second driving unit 20, and the movable part 30 are driven in opposite phases, it is also possible to perform control such that the first driving unit 10 and the second driving unit 20, and the movable part 30 are driven in the same phase.

Meanwhile, when the driving element 1 is used as a light deflecting element as described above, the deflection angle of the movable part 30 is preferably as large as possible. Accordingly, scanning can be performed with light over a wider range. In addition, when the arm parts are bent to vibrate the movable part 30 as described above, the piezoelectric drivers 17a, 17b, 27a, and 27b may be damaged by stress (torsion) generated in the first arm parts 11a, 11b, 21a, and 21b during driving. This problem becomes more apparent when the pairs of first arm parts 11a, 11b, 21a, and 21b are bent to a greater extent in order to increase the deflection angle.

On the other hand, in the present embodiment, as described above, in addition to the pairs of first arm parts 11a, 11b, 21a, and 21b, the pairs of second arm parts 12a, 12b, 22a, and 22b are disposed, and the above two problems are solved simultaneously by the action of these pairs of second arm parts 12a, 12b, 22a, and 22b. That is, in the present embodiment, as compared to the conventional configuration in which the pairs of second arm parts 12a, 12b, 22a, and 22b are not disposed, the deflection angle of the movable part 30 can be increased, and stress (torsion) generated in the first arm parts 11a, 11b, 21a, and 21b can be reduced. Accordingly, the deflection angle of the movable part 30 can be further increased while damaging the piezoelectric drivers 17a, 17b, 27a, and 27b by stress (torsion) is suppressed.

<Examination 1>

The inventors examined stress generated in each part during driving, by simulation, for the driving element 1 configured as described above. In addition, as a comparative example, the inventors examined stress generated in each part during driving, by simulation, for a configuration in which the second arm parts 12a, 12b, 22a, and 22b were omitted from the above configuration.

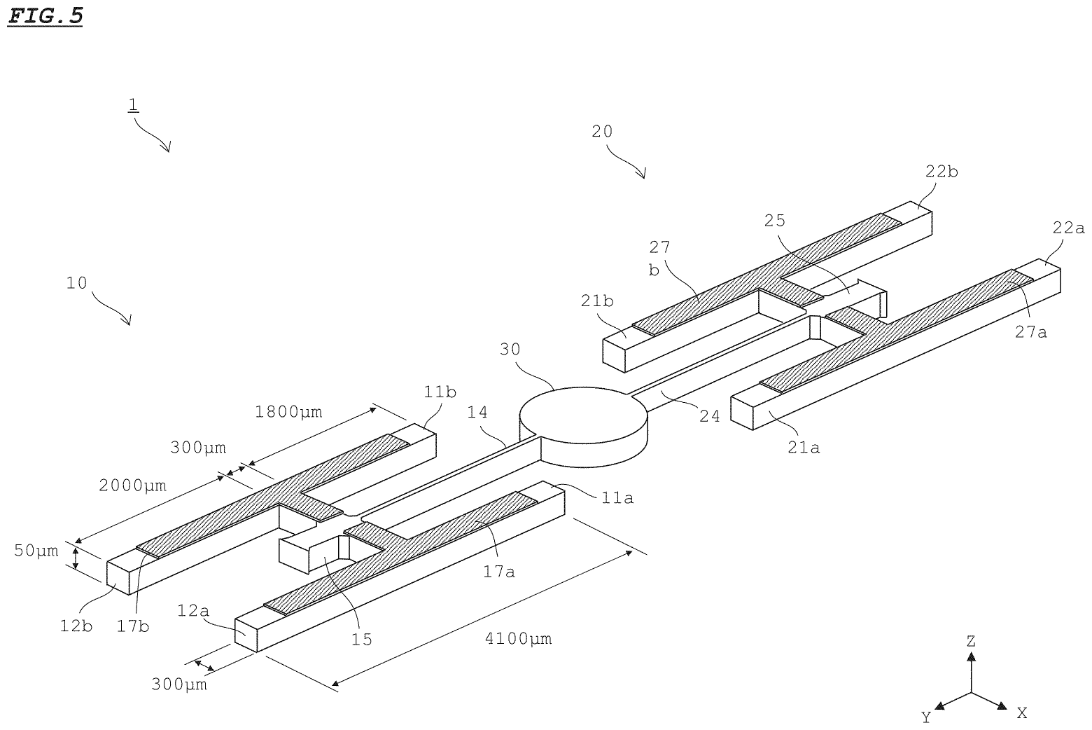

FIG. 5 is a diagram showing the dimensions of each part used in the simulation.

As in the above configuration, the driving element 1 has a shape symmetrical in the Y-axis direction and symmetrical in the X-axis direction in a plan view. In the examination, the thickness of the driving element 1 excluding the piezoelectric drivers 17a, 17b, 27a, and 27b and the reflection surface 40 was set uniformly to 50 μm. Under the conditions in FIG. 5, the stress of each part was obtained when AC voltages having a predetermined frequency and a predetermined amplitude were applied to the piezoelectric drivers 17a and 27a and the piezoelectric drivers 17b and 27b in opposite phases.

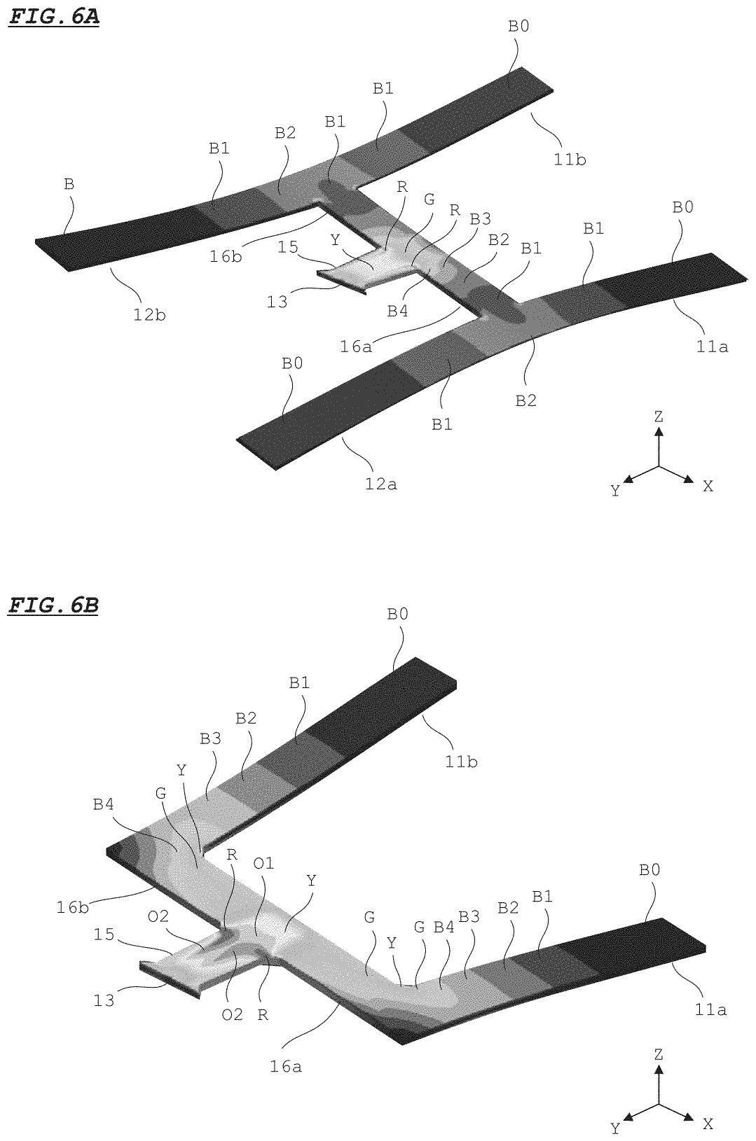

FIG. 6A is a diagram showing a stress distribution simulation result for the embodiment, and FIG. 6B is a diagram showing a stress distribution simulation result for the comparative example.

In the simulation results in FIGS. 6A and 6B, color images are gray-scaled. In the actual color images, dark blue is set as a color having the lowest stress, and red is set as a color having the highest stress. In addition, in FIGS. 6A and 6B, the magnitude of stress is shown stepwise. B0 to B4 indicate a blue range, G indicates a green range, and Y indicates a yellow range. O1 and O2 indicate an orange range, and R indicates a red range. The stress is higher in the order of red (highest), orange, yellow, green, and blue (lowest). In addition, in the blue range, the stress is higher in the order of B4 (highest), B3, B2, B1, and B0 (lowest), and in the orange range, the stress is higher in the order of O2 (high) and O1 (low).

As shown in FIG. 6B, in the comparative example, the stress is high at bent portions from the first arm parts 11a and 11b to the coupling parts 16a and 16b. In addition, at the bent portions, the stress distribution is non-uniform, so that it is found that strong torsion is generated in the bent portions. Furthermore, in the comparative example, the stress is high in substantially the entire ranges of the coupling parts 16a and 16b. From this, it is inferred that in the comparative example, especially at the bent portions, high stress and torsion act on the piezoelectric drivers, and the piezoelectric drivers are likely to be damaged. It is also inferred that at the coupling parts 16a and 16b, high stress and torsion also act on the piezoelectric drivers, and the piezoelectric drivers are likely to be damaged.

On the other hand, in the embodiment, as shown in FIG. 6A, the stress is significantly low at bent portions from the first arm parts 11a and 11b and the second arm parts 12a and 12b to the coupling parts 16a and 16b. In addition, at these bent portions, the stress distribution is not non-uniform, so that it is found that substantially no torsion is generated in the bent portions. Furthermore, in the embodiment, the stress is low in substantially the entire ranges of the coupling parts 16a and 16b. From this, it is inferred that in the embodiment, at the bent portions, the piezoelectric drivers are not damaged, and are also less likely to be damaged at the coupling parts 16a and 16b. This is inferred to be because, by providing the second arm parts 12a and 12b, the driving unit is driven such that no torsion is generated in the coupling parts 16a and 16b (driven in a so-called pure bending mode).

From the above examination, it is confirmed that in the configuration of the embodiment, by disposing the pair of second arm parts 12a and 12b, stress generated in each part during driving can be significantly reduced. It is also confirmed that under the dimensional conditions shown in FIG. 5, by setting the lengths of the second arm parts 12a and 12b to a proper value (here, 2000 μm), torsion can be prevented from being generated in the bent portions. Accordingly, it is confirmed that in the configuration of the embodiment, damaging the piezoelectric drivers by stress and torsion during driving is prevented.

To suppress concentration and generation of stress, due to torsion, at the connection portions (above bent portions) between the first arm parts 11a and 11b and the second arm parts 12a and 12b, and the coupling parts 16a and 16b and at the coupling parts 16a and 16b during driving, it is sufficient that torques generated in opposite directions by the first arm parts 11a and 11b and the second arm parts 12a and 12b with the connection portions as centers (torques parallel to the Y-Z plane) are balanced with each other. In addition, as a result of adjusting the two torques as described above, during driving, the connection portions move substantially in the up-down direction to a great extent, thereby allowing the movable part 30 and the reflection surface 40 to rotate at a large deflection angle.

<Examination 2>

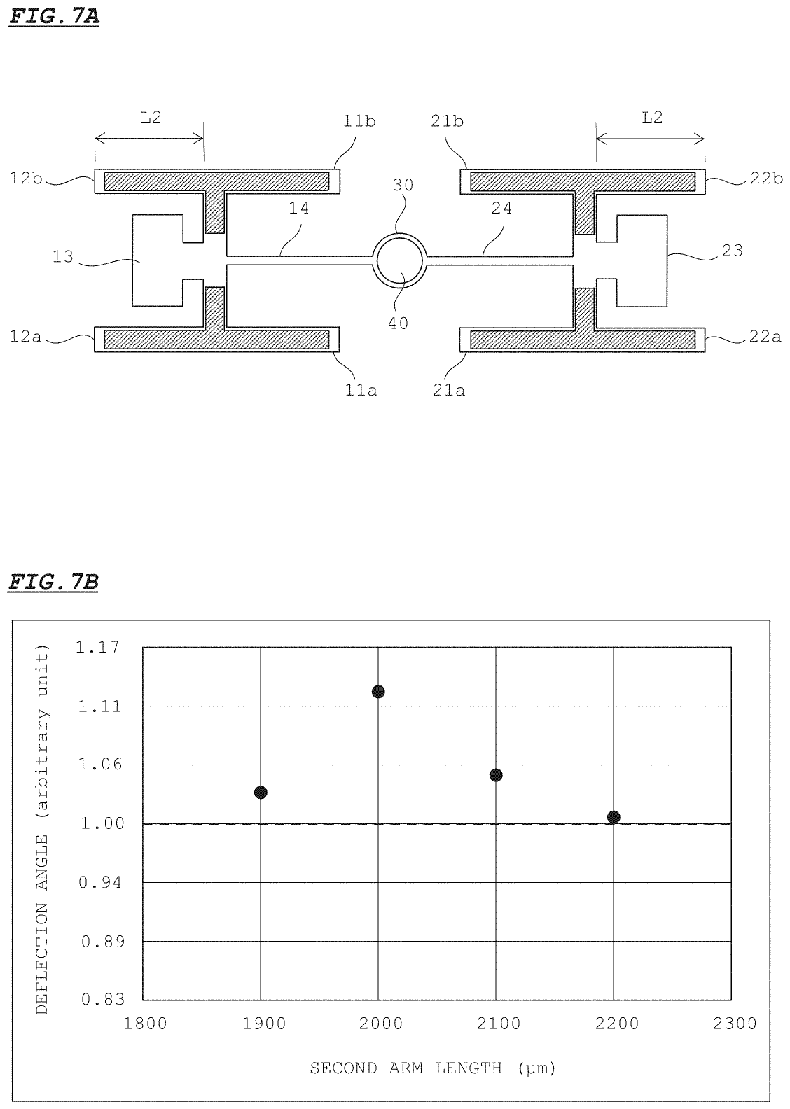

Next, the inventors experimentally examined the deflection angle characteristics of the movable part 30 when lengths L2 of the second arm parts 12a, 12b, 22a, and 22b shown in FIG. 7A were varied. In the examination, the dimensions other than the lengths L2 were set to be the same as in FIG. 5. In addition, the inventors also experimentally examined the deflection angle characteristics for the same comparative example as in Examination 1 described above.

FIG. 7B is a graph showing the examination results of the deflection angle characteristics.

Here, the lengths L2 of the second arm parts 12a, 12b, 22a, and 22b are set to four types of 1900 μm, 2000 μm, 2100 μm, and 2200 μm. In FIG. 7B, a broken line indicates the examination results of the deflection angle for the comparative example. In FIG. 7B, the vertical axis indicates the deflection angle per unit voltage, and is normalized by the deflection angle of the comparative example.

As shown in FIG. 7B, by setting the lengths L2 of the second arm parts 12a, 12b, 22a, and 22b to 1900 to 2100 μm, the deflection angle characteristics are enhanced as compared to those of the comparative example. In particular, when the lengths L2 of the second arm parts 12a, 12b, 22a, and 22b were set to 2000 μm, significantly high deflection angle characteristics that were about 1.13 times those of the comparative example were obtained.

From the above examination, it is confirmed that in the configuration of the embodiment, by disposing the second arm parts 12a, 12b, 22a, and 22b and optimizing the lengths thereof, the deflection angle characteristics of the movable part 30 can be significantly enhanced. Therefore, in the configuration of the embodiment, the range of scanning with light can be significantly expanded by locating the reflection surface 40 on the movable part 30.

Referring to FIG. 7B, it can be inferred that the lengths L2 of the second arm parts 12a, 12b, 22a, and 22b that can enhance the deflection angle characteristics as compared to the comparative example are limited to a certain range. Therefore, it can be said that the lengths L2 of the second arm parts 12a, 12b, 22a, and 22b need to be set to be at least in this range.

### Effects of Embodiment

According to the present embodiment, the following effects are achieved.

As shown in Examinations 1 and 2 described above, by providing the pairs of second arm parts 12a, 12b, 22a, and 22b, torsion and stress generated in the first arm parts 11a, 11b, 21a, and 21b and the second arm parts 12a, 12b, 22a, and 22b when the piezoelectric drivers 17a, 17b, 27a, and 27b are driven can be reduced, and the deflection angle of the movable part 30 when the piezoelectric drivers 17a, 17b, 27a, and 27b are driven can be increased. Therefore, damaging the piezoelectric drivers 17a, 17b, 27a, and 27b by stress generated during driving can be suppressed while the deflection angle of the movable part 30 is increased.

As shown in FIG. 1, the piezoelectric drivers 17a, 17b, 27a, and 27b are disposed on both the pairs of first arm parts 11a, 11b, 21a, and 21b and the pairs of second arm parts 12a, 12b, 22a, and 22b. Accordingly, larger torque can be generated, so that the deflection angle of the movable part 30 can be more effectively increased.

As shown in FIG. 1, the piezoelectric drivers 17a, 17b, 27a, and 27b are further disposed on the coupling parts 16a, 16b, 26a, and 26b. Accordingly, even larger torque can be generated, so that the deflection angle of the movable part 30 can be even more effectively increased.

As shown in Examination 1 described above, the lengths of the second arm parts 12a, 12b, 22a, and 22b are preferably set such that substantially no torsion is generated in the first arm parts 11a, 11b, 21a, and 21b. Accordingly, damaging the piezoelectric drivers 17a, 17b, 27a, and 27b by stress generated during driving can be more reliably prevented.

As shown in Examination 2 described above, the lengths of the second arm parts 12a, 12b, 22a, and 22b are preferably set such that the deflection angle of the movable part 30 is maximized when the movable part 30 is vibrated around the rotation axis R0 at a target frequency. Accordingly, the movable part 30 can be vibrated at a larger deflection angle, so that the driving element 1 can be operated most efficiently.

As shown in FIG. 1, two driving units, that is, the first driving unit 10 and the second driving unit 20, are disposed in opposite orientations with the movable part 30 located therebetween, and the first connection parts 14 and 24 of the respective driving units are connected to the movable part 30. By supporting and driving the movable part 30 by the respective driving units as described above, the movable part 30 can be stably driven with larger torque.

As shown in FIG. 1, the reflection surface 40 is located on the movable part 30. Accordingly, scanning can be performed at a larger deflection angle with light (e.g., laser beam) incident on the reflection surface 40, so that the range of scanning with light can be expanded.

As shown in FIG. 1, the widths of the second connection parts 15 and 25 are set so as to be larger than those of the first connection parts 14 and 24. By designing the torsional rigidity of the second connection parts 15 and 25 to be higher than that of the first connection parts 14 and 24, leakage vibrations of the first driving unit 10 and the second driving unit 20 are less likely to be transmitted to the bases 13 and 23, resulting in a larger Q value.

<Modification 1>

In the above embodiment, the piezoelectric drivers 17a, 17b, 27a, and 27b are disposed on the first arm parts 11a, 11b, 21a, and 21b, the second arm parts 12a, 12b, 22a, and 22b, and the coupling parts 16a, 16b, 26a, and 26b, but the method for disposing the piezoelectric drivers 17a, 17b, 27a, and 27b is not limited thereto.

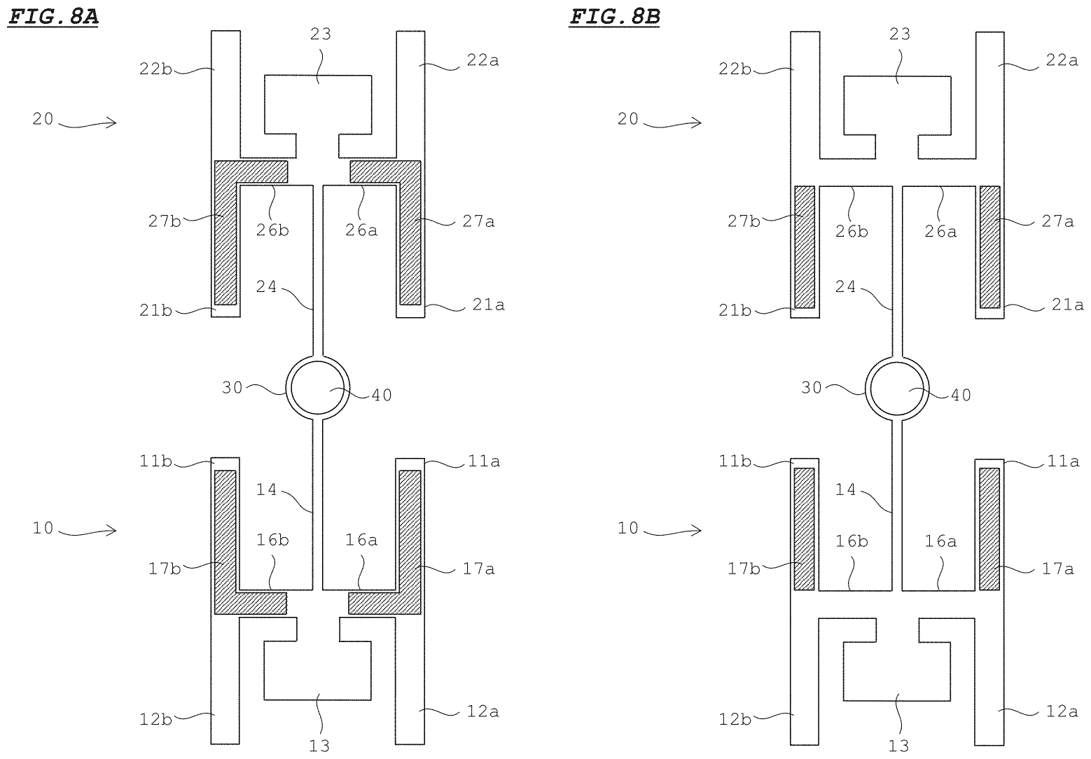

FIGS. 8A and 8B are each a plan view illustrating another method for disposing the piezoelectric drivers 17a, 17b, 27a, and 27b.

In the disposing methods in FIGS. 8A and 8B, the piezoelectric drivers 17a, 17b, 27a, and 27b are not disposed on the second arm parts 12a, 12b, 22a, and 22b. In FIG. 8A, the piezoelectric drivers 17a, 17b, 27a, and 27b are disposed on the first arm parts 11a, 11b, 21a, and 21b and the coupling parts 16a, 16b, 26a, and 26b, and in FIG. 8B, the piezoelectric drivers 17a, 17b, 27a, and 27b are disposed only on the first arm parts 11a, 11b, 21a, and 21b.

Even with these disposing methods, the second arm parts 12a, 12b, 22a, and 22b serve as balancers for the first arm parts 11a, 11b, 21a, and 21b. Therefore, non-uniform and large stress can be inhibited from being generated in the bent portions from the first arm parts 11a, 11b, 21a, and 21b and the second arm parts 12a, 12b, 22a, and 22b to the coupling parts 16a, 16b, 26a, and 26b during driving. Therefore, damaging the piezoelectric drivers 17a, 17b, 27a, and 27b by stress and torsion generated during driving can be prevented.

Also, in the configurations in FIGS. 8A and 8B, when the first arm parts 11a, 11b, 21a, and 21b are driven by the piezoelectric drivers 17a, 17b, 27a, and 27b, the reaction thereof causes the second arm parts 12a, 12b, 22a, and 22b to bend in the up-down direction. Accordingly, torques are generated not only by the first arm parts 11a, 11b, 21a, and 21b but also by the second arm parts 12a, 12b, 22a, and 22b, and these torques cause the movable part 30 to rotate to a greater extent. Therefore, in the configurations in FIGS. 8A and 8B as well, the deflection angle of the movable part 30 can be increased as compared to that of the above comparative example.

The inventors set the dimensions of each part of the driving element 1 to the dimensions shown in FIG. 5, placed the piezoelectric drivers 17a, 17b, 27a, and 27b as shown in FIG. 8A, and experimentally examined the deflection angle characteristics of the movable part 30. In this examination, the lengths of the second arm parts 12a, 12b, 22a, and 22b were set to 2000 μm. As a result of the examination, a deflection angle of the movable part 30 that was about 1.07 times that of the above comparative example was obtained. This deflection angle was lower by about 5% than the deflection angle in the configuration of the embodiment in Examination 2 described above (1.12 times that of the comparative example), but was significantly increased from the deflection angle for the above comparative example.

From the examination results, it is confirmed that even when the piezoelectric drivers 17a, 17b, 27a, and 27b are disposed as shown in FIGS. 8A and 8B described above, the deflection angle of the movable part 30 can be significantly increased by the action of the second arm parts 12a, 12b, 22a, and 22b.

Also, in the configuration examples in FIGS. 8A and 8B, as in the above embodiment, preferably, the lengths of the second arm parts 12a, 12b, 22a, and 22b are optimized. That is, preferably, the lengths of the second arm parts 12a, 12b, 22a, and 22b are optimized such that the piezoelectric drivers 17a, 17b, 27a, and 27b are not damaged by stress and torsion generated during driving and the deflection angle of the movable part 30 is maximized at the target frequency. Accordingly, when the reflection surface 40 is located on the movable part 30, the range of scanning with light (e.g., laser beam) can be significantly expanded.

Also, in the configuration examples in FIGS. 8A and 8B described above, since the areas of the piezoelectric drivers 17a, 17b, 27a, and 27b are smaller than those in the configuration example in FIG. 1, there is a merit that the power consumption during driving is reduced.

<Modification 2>

In the above embodiment and Modification 1, the first driving unit 10 and the second driving unit 20 are disposed in the driving element 1, but only one of the first driving unit 10 and the second driving unit 20 may be disposed in the driving element 1.

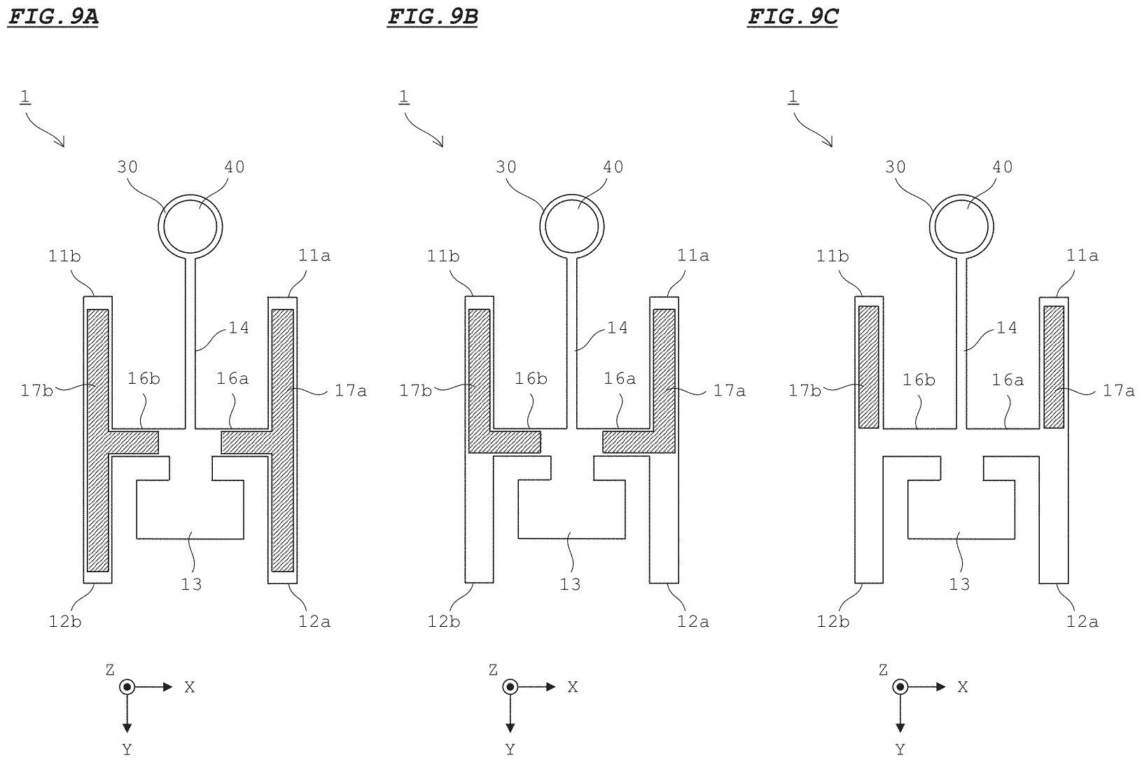

FIG. 9A to FIG. 9C are each a plan view showing a configuration of the driving element 1 when only the first driving unit 10 is disposed.

The configuration of each part shown in FIG. 9A to FIG. 9C is the same as the configuration of each part of the first driving unit 10 in the above embodiment. The movable part 30 is connected only at an end portion thereof on the Y-axis positive side to the first connection part 14.

In this case as well, as in the above embodiment and Modification 1, the piezoelectric drivers 17a and 17b can be disposed on the first arm parts 11a and 11b, the second arm parts 12a and 12b, and the coupling parts 16a and 16b as shown in FIG. 9A. Alternatively, the piezoelectric drivers 17a and 17b may be disposed on the first arm parts 11a and 11b and the coupling parts 16a and 16b as shown in FIG. 9B, or the piezoelectric drivers 17a and 17b may be disposed only on the first arm parts 11a and 11b as shown in FIG. 9C.

Even with these configurations, as in the above embodiment and Modification 1, as compared to a configuration in which the second arm parts 12a and 12b are omitted from these configurations, torsion can be inhibited from being generated in the first arm parts 11a and 11b, and the deflection angle of the movable part 30 can be increased. Therefore, damaging the piezoelectric drivers 17a and 17b by torsion and stress in the first arm parts 11a and 11b can be prevented, and the deflection angle characteristics of the movable part 30 can be enhanced.

The configurations in FIGS. 9A, 9B, and 9C also allow the entire size of the driving element 1 to be reduced, and as a result, there is a merit that the size and the cost of the driving element 1 can be reduced.

In these configurations as well, as in the above embodiment, preferably, the lengths of the second arm parts 12a and 12b are optimized. That is, preferably, the lengths of the second arm parts 12a and 12b are optimized such that the piezoelectric drivers 17a and 17b are not damaged by stress and torsion generated during driving and the deflection angle of the movable part 30 is maximized at the target frequency. Accordingly, when the reflection surface 40 is located on the movable part 30, the range of scanning with light (e.g., laser beam) can be significantly expanded.

<Other Modifications>

In the above embodiment and Modifications 1 and 2, the shape of the movable part 30 is a circular shape, but the shape of the movable part 30 may be another shape such as a square shape. In addition, in the above embodiment and Modifications 1 and 2, the first connection parts 14 and 24 extend in a straight manner and are connected to the second connection parts 15 and 25, respectively, but the first connection parts 14 and 24 may each be branched at the end portion thereof on the Y-axis positive side into two portions and be connected to the second connection parts 15 and 25, respectively. In addition, the first connection parts 14 and 24 do not have to have a plate shape, and may have, for example, a rectangular bar shape.

In the above embodiment and Modifications 1 and 2, the first arm parts 11a, 11b, 21a, and 21b and the second arm parts 12a, 12b, 22a, and 22b are disposed so as to be linearly aligned in the Y-axis direction, but the second arm parts 12a, 12b, 22a, and 22b may be disposed so as to be displaced slightly in the X-axis direction with respect to the first arm parts 11a, 11b, 21a, and 21b.

In the above embodiment and Modifications 1 and 2, the first arm parts 11a, 11b, 21a, and 21b are parallel to the rotation axis R0, but the first arm parts 11a, 11b, 21a, and 21b may be tilted with respect to the rotation axis R0. For example, the first arm parts 11a, 11b, 21a, and 21b may be tilted in the X-axis direction with respect to the rotation axis R0 such that the distance between the first arm parts 11a and 11b increases and the distance between the first arm parts 21a and 21b increases as the distance to the movable part 30 decreases. Similarly, the second arm parts 12a, 12b, 22a, and 22b may be tilted in at least one of the X-axis direction and the Y-axis direction with respect to the rotation axis R0. It is sufficient that the direction in which the first arm parts extend includes a component in the first direction parallel to the rotation axis R0, and it is sufficient that the direction in which the second arm parts extend includes a component in the second direction opposite to the first direction.

The shapes of the first arm parts 11a, 11b, 21a, and 21b and the second arm parts 12a, 12b, 22a, and 22b are also not limited to the shapes shown in the above embodiment and Modifications 1 and 2. For example, the first arm parts 11a, 11b, 21a, and 21b and the second arm parts 12a, 12b, 22a, and 22b may have a trapezoidal shape in a plan view such that the widths of the first arm parts 11a, 11b, 21a, and 21b and the second arm parts 12a, 12b, 22a, and 22b narrow toward the ends thereof. In this case, as the weights of the first arm parts 11a, 11b, 21a, and 21b and the second arm parts 12a, 12b, 22a, and 22b are reduced, the deflection angle of the movable part 30 increases, but the resonance frequency of the driving element 1 decreases slightly.

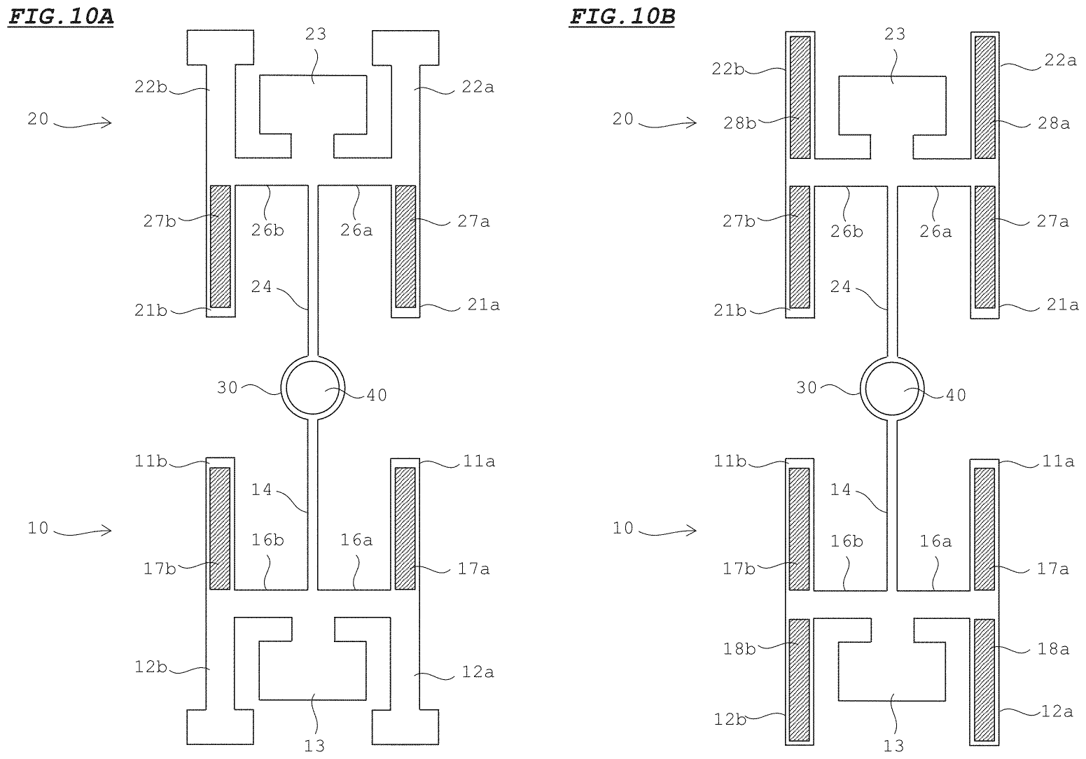

Alternatively, the widths of the first arm parts 11a, 11b, 21a, and 21b and the second arm parts 12a, 12b, 22a, and 22b may be widened stepwise, and, for example, as shown in FIG. 10A, the end portions of the second arm parts 12a, 12b, 22a, and 22b may be widened in a rectangular shape. In addition, the widths of the second arm parts 12a, 12b, 22a, and 22b may be larger than the widths of the first arm parts 11a, 11b, 21a, and 21b, or the thicknesses of the first arm parts 11a, 11b, 21a, and 21b and the thicknesses of the second arm parts 12a, 12b, 22a, and 22b may be different from each other.

The shapes of the first arm parts 11a, 11b, 21a, and 21b and the second arm parts 12a, 12b, 22a, and 22b may be set to shapes that allow the deflection angle of the movable part 30 and the resonance frequency to be adjusted to predetermined values. As described above, the second arm parts 12a, 12b, 22a, and 22b may serve as balance adjustment parts for generating torque with the connection portions between the first arm parts 11a, 11b, 21a, and 21b and the second arm parts 12a, 12b, 22a, and 22b, and the coupling parts 16a and 16b as centers and causing this torque and torque generated by the first arm parts 11a, 11b, 21a, and 21b to approach a balanced state with each other during driving. Accordingly, as described above, torsion generated in these connection portions and the coupling parts 16a and 16b can be reduced, and the deflection angle of the movable part 30 and the reflection surface 40 can be increased.

In the above embodiment and Modification 1, the driving element 1 has a shape symmetrical in the X-axis direction and the Y-axis direction in a plan view, but the driving element 1 may have a shape slightly asymmetrical in the X-axis direction or the Y-axis direction in a plan view. Similarly, the driving element 1 according to Modification 2 may have a shape slightly asymmetrical in the X-axis direction.

Also, the method for disposing the piezoelectric drivers 17a, 17b, 27a, and 27b is not limited to the disposing methods shown in the above embodiment and Modifications 1 and 2, and, for example, the piezoelectric drivers 17a, 17b, 27a, and 27b may not necessarily be disposed on the coupling parts 26a and 26b and may be disposed so as to extend in a straight manner from the first arm parts 11a, 11b, 21a, and 21b to the second arm parts 12a, 12b, 22a, and 22b. Alternatively, the piezoelectric drivers 17a, 17b, 27a, and 27b may be disposed only on the second arm parts 12a, 12b, 22a, and 22b.

Alternatively, as shown in FIG. 10B, the piezoelectric drivers 17a, 17b, 18a, 18b, 27a, 27b, 28a, and 28b may be disposed on the first arm parts 11a, 11b, 21a, and 21b and the second arm parts 12a, 12b, 22a, and 22b (balance adjustment parts), respectively. In this case, torque generated by the first arm parts 11a, 11b, 21a, and 21b and torque generated by the second arm parts 12a, 12b, 22a, and 22b may be balanced with each other by controlling the driving operation of each piezoelectric driver.

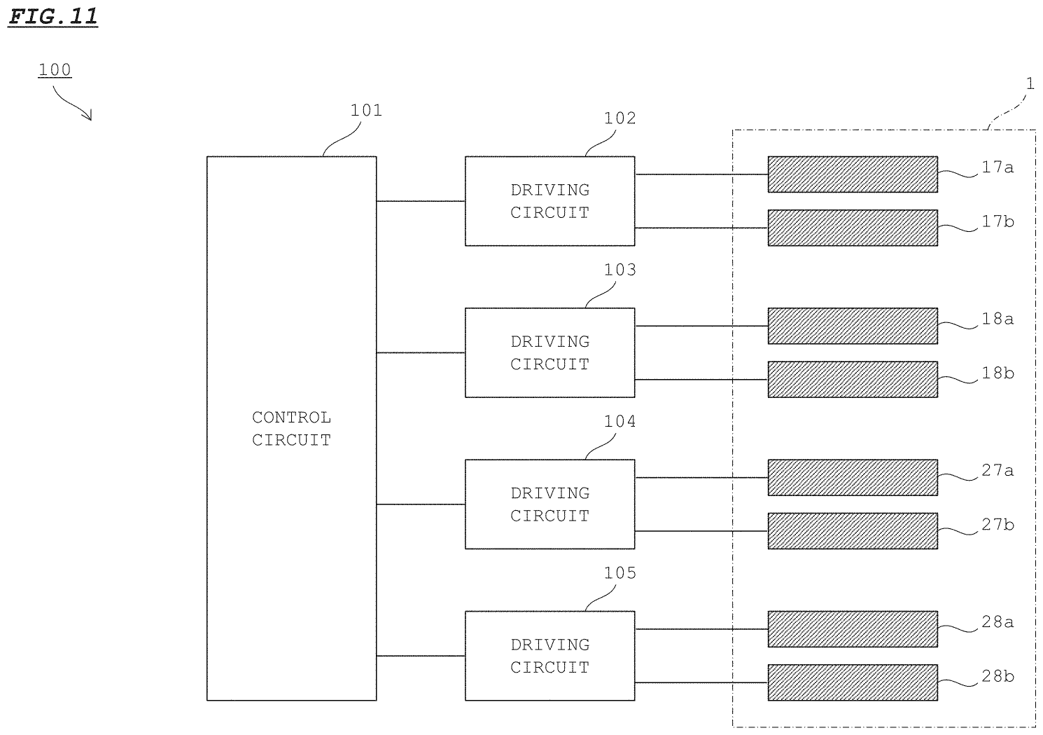

In this case, a driving device 100 is configured as shown in FIG. 11. The driving device 100 includes the driving element 1 shown in FIG. 10B, a control circuit 101, and four driving circuits 102 to 105. For convenience, only the configurations of the piezoelectric drivers 17a, 17b, 18a, 18b, 27a, 27b, 28a, and 28b among the components of the driving element 1 are shown in FIG. 11.

The control circuit 101 includes a microcomputer, and controls the driving circuits 102 to 105 according to a program stored therein in advance. The driving circuit 102 supplies a driving signal to the piezoelectric drivers 17a and 17b under control from the control circuit 101, the driving circuit 103 supplies a driving signal to the piezoelectric drivers 18a and 18b under control from the control circuit 101, the driving circuit 104 supplies a driving signal to the piezoelectric drivers 27a and 27b under control from the control circuit 101, and the driving circuit 105 supplies a driving signal to the piezoelectric drivers 28a and 28b under control from the control circuit 101.

During driving, the driving circuits 102 to 105 drive the piezoelectric drivers 17a, 17b, 18a, 18b, 27a, 27b, 28a, and 28b such that the first arm parts 11a and 21a and the second arm parts 12a and 22a on the X-axis positive side, and the first arm parts 11b and 21b and the second arm parts 12b and 22b on the X-axis negative side are driven in opposite directions as described with reference to FIGS. 4A and 4B. At this time, the driving circuits 102 to 105 further drive the respective piezoelectric drivers, such that torsion at the connection portions between the first arm parts 11a, 11b, 21a, and 21b and the second arm parts 12a, 12b, 22a, and 22b (balance adjustment parts), and the coupling parts 16a, 16b, 26a, and 26b is reduced, to rotate the movable part 30 about the rotation axis R0. That is, the driving circuits 102 to 105 drive the respective piezoelectric drivers such that torques generated in opposite directions by the first arm parts 11a, 11b, 21a, and 21b and the second arm parts 12a, 12b, 22a, and 22b with the connection portions as centers approach a balanced state with each other. Accordingly, as described above, torsion generated in these connection portions and the coupling parts 16a and 16b can be reduced, and the deflection angle of the movable part 30 and the reflection surface 40 can be increased.

In this configuration, since the two torques in directions opposite to each other are caused to approach a balanced state by driving and controlling the respective piezoelectric drivers, the lengths of the second arm parts 12a, 12b, 22a, and 22b (balance adjustment part) do not necessarily have to be set in the preferred range shown in FIG. 7A.

In the case where the driving device 100 includes any one of the driving elements 1 shown in the above embodiment and Modifications 1 and 2, the number of the driving circuits 102 to 105 in FIG. 11 is changed according to the number of piezoelectric drivers disposed in the driving element 1. For example, in the case where the driving element 1 included in the driving device 100 has the configuration in FIG. 1, the driving circuits 103 and 105 are omitted from the configuration in FIG. 11. In this case, the driving circuits 102 and 104 also drive the piezoelectric drivers 17a, 17b, 27a, and 27b, such that torsion at the above connection portions is reduced, to rotate the movable part 30 about the rotation axis R0. In this configuration as well, as in the above, the lengths of the second arm parts 12a, 12b, 22a, and 22b (balance adjustment parts) do not necessarily have to be set in the preferred range shown in FIG. 7A.

The dimensions of each part of the driving element 1 are also not limited to the dimensions shown in FIG. 5, and can be changed as appropriate. When the dimensions of each part are changed, the dimensions of the second arm parts 12a, 12b, 22a, and 22b may be optimized according to the change.

In the case where the driving element 1 is used as an element other than a light deflecting element, the reflection surface 40 may not necessarily be located on the movable part 30, and another member other than the reflection surface 40 may be disposed on the movable part 30.

In addition to the above, various modifications can be made as appropriate to the embodiment of the present invention, without departing from the scope of the technological idea defined by the claims.

What is claimed is:

1. A driving element comprising:
a base;
a movable part spaced apart from the base in a direction parallel to a rotation axis;
a connection part connecting the base and the movable part;
a pair of first arm parts extending in a first direction parallel to the rotation axis with the rotation axis located therebetween;
a pair of second arm parts extending in a second direction opposite to the first direction, with the rotation axis located therebetween;
a coupling part coupling the pair of first arm parts and the pair of second arm parts to the connection part; and
a piezoelectric driver disposed on at least either the pair of first arm parts or the pair of second arm parts.

2. The driving element according to claim 1, wherein the piezoelectric driver is disposed on both the pair of first arm parts and the pair of second arm parts.

3. The driving element according to claim 1, wherein the piezoelectric driver is disposed on the pair of first arm parts, and is not disposed on the pair of second arm parts.

4. The driving element according to claim 1, wherein the piezoelectric driver is further disposed on the coupling part.

5. The driving element according to claim 1, wherein lengths of the second arm parts are set such that substantially no torsion is generated in at least the first arm parts.

6. The driving element according to claim 1, wherein lengths of the second arm parts are set such that a deflection angle of the movable part is maximized when the movable part is vibrated around the rotation axis at a target frequency.

7. The driving element according to claim 1, wherein
two driving units each including the base, the connection part, the pair of first arm parts, the pair of second arm parts, the coupling part, and the piezoelectric driver are disposed in orientations opposite to each other with the movable part located therebetween, and
the connection part of each of the driving units is connected to the movable part.

8. The driving element according to claim 1, wherein a reflection surface is located on the movable part.

9. A driving element comprising:
a base;
a movable part spaced apart from the base in a direction parallel to a rotation axis;
a connection part connecting the base and the movable part;
a pair of arm parts extending in a first direction parallel to the rotation axis with the rotation axis located therebetween;
a pair of balance adjustment parts extending in a second direction opposite to the first direction, with the rotation axis located therebetween;
a coupling part coupling the pair of arm parts and the pair of balance adjustment parts to the connection part; and
a piezoelectric driver disposed on at least either the pair of arm parts or the pair of balance adjustment parts.

10. The driving element according to claim 9, wherein
two driving units each including the base, the connection part, the pair of arm parts, the pair of balance adjustment parts, the coupling part, and the piezoelectric driver are disposed in orientations opposite to each other with the movable part located therebetween, and
the connection part of each of the driving units is connected to the movable part.

11. The driving element according to claim 9, wherein a reflection surface is located on the movable part.

12. A driving device comprising:
a driving element; and
a driving circuit configured to supply a driving voltage to a piezoelectric driver, wherein
the driving element includes
a base,
a movable part spaced apart from the base in a direction parallel to a rotation axis,
a connection part connecting the base and the movable part,
a pair of arm parts extending in a first direction parallel to the rotation axis with the rotation axis located therebetween,
a pair of balance adjustment parts extending in a second direction opposite to the first direction, with the rotation axis located therebetween,
a coupling part coupling the pair of arm parts and the pair of balance adjustment parts to the connection part, and
the piezoelectric driver disposed on at least either the pair of arm parts or the pair of balance adjustment parts.

13. The driving device according to claim 12, wherein
the piezoelectric driver is disposed on each of the pair of arm parts and the pair of balance adjustment parts, and
the driving circuit drives the piezoelectric driver, such that torsion at connection portions between the arm parts and the balance adjustment parts, and the coupling part is reduced, to rotate the movable part about the rotation axis.
